(19) United States
(12) Patent Application Publication
(10) Pub. No.: US 2012/0247538 A1
(43) Pub. Date: Oct. 4, 2012

(54) EFFICIENT HEAT SINK FOR SOLAR PHOTOVOLTAIC CELLS AND A COMBINED HEAT AND POWER GENERATION SYSTEM

(75) Inventors: Yaohua Zhao, Beijing (CN); Kairong Zhang, Beijing (CN); Yanhua Diao, Beijing (CN)

(73) Assignee: NANJING ECOWAY ENERGY TECHNOLOGY CO., LTD., Nanjing, Jiangsu (CN)

(21) Appl. No.: 13/518,783

(22) PCT Filed: Dec. 21, 2010
(86) PCT No.: PCT/CN10/80068

§ 371 Date: Jun. 22, 2012

(30) Foreign Application Priority Data
Dec. 25, 2009 (CN) 200910260246.1

(51) Int. Cl. H01L 31/052; H01L 31/058; F28D 15/04

(52) U.S. Cl. 136/248; 136/246; 165/104.26

(57) ABSTRACT

An efficient heat sink for solar photovoltaic cells and a combined heat and power generation system include one or more flat plate heat pipes. A front plate surface of the front and back plate surfaces engages with and covers the backplate of the cell plate. A heat exchanger of plate pipe type engages with the cooling portion of backplate surface of the flat plate heat pipe. Heat absorbed by the heat absorption surface of the flat plate heat pipe from the cell plate is dissipated by the heat exchanger through cooling media without affecting combination of the cell plate with a building surface or application of the cell plate as a building component. Therefore, the temperature of the cell plate is prevented from rising, the dissipated heat may be utilized to generate hot water, solar utilization efficiency is improved, and the cost of the solar photovoltaic industry is reduced.

### TECHNICAL FIELD

The invention relates to the field of solar utilization technology, particularly relates to an efficient heat sink for solar photovoltaic cells and a combined heat and power generation system employing the heat sink.

### BACKGROUND ART

The maximum photoelectric conversion efficiency of a general commercially available photovoltaic cell is only about 15%, and most of the unemployed solar radiation energy is absorbed by the cell and converted into heat. If the absorbed heat cannot be utilized (as waste heat) or not be removed in time, the cell temperature will increase gradually and the power generation efficiency will be decreased. Furthermore, the service life of the photovoltaic cell will be shortened due to rapid aging resulting from persistent working at high temperatures. Even for the traditional solar power generation cell of non focusing type, its cell temperature usually reaches 70-80° C. in seasons other than winter, and its practical photoelectric conversion efficiency amounts to only about 7-10%. Local damage is likely to be caused due to local overheated spots. Especially, in the case that solar photovoltaic cells and the building are integratedly designed and therefore a building envelope has to be designed to facilitate heat dissipation, an acerb contradiction arises between cooling of the backplate of the photovoltaic cell and heat insulation of the building envelope. In the prior art, neither is the waste heat from the photovoltaic cell made full use of, nor is an efficient cooling method developed. Therefore, the heat from the cell backplates is directly discharged into the interior of the building, or the temperature of the cell backplates at the presence of insulating structure becomes much higher than in the case of being deployed in field (e.g., the local temperature may exceed 100° C., which severely deteriorates the cell endurance). Therefore, integral design of the solar photovoltaic power generation system with building cannot be put into practice use nowadays.

In addition, reflectors or lens of low cost are employed in concentrating photovoltaic power generation technology (CPV) to decrease the number of expensive solar cells. In this case, the photovoltaic cell works under light irradiation of low and even high multiple intensity, thus its effective output power of per unit area is increased significantly and the cost of the power generation is reduced greatly. However, with increase of the radiation light intensity per unit area, heat that is absorbed is increased. The local temperature of the chip is increased due to high focusing, which affects the photovoltaic efficiency severely and limits the increase of the focusing multiple, and hence becomes the core technical challenge in field of high focusing photovoltaic.

The important topic that will advance the explosive development of the solar photovoltaic industry is how to realize efficient cooling of the solar photovoltaic cell, and how to fully utilize the waste heat of the cell in an economic way.

In Chinese patent application No. 200810239002.0 titled A Heat Sink of Photovoltaic Cell, filed by the applicant, an efficient heat sink for photovoltaic cells is disclosed. In this heat sink, the heat absorption surface of the cooling plate of the micro heat pipe formed by micro tube or micro groove therein contacts with the backplate of the photovoltaic cell, and a part or all of the rest sides is the cooling surface. The heat sink can efficiently and quickly absorb the heat accumulated in the photovoltaic cell, decrease the temperature of the photovoltaic cell, and hence fulfill the goal of efficient cooling. However, the heat sink conducts cooling through the surface that does not contact with the photovoltaic cell, or part of the surface is located in a heat exchanger. In the case that the heat sink is used in a building, it is necessary to make the surface of backing of the heat absorption surface of the cooling plate contact with the building, or to locate it within the building, so the backing can not function as the cooling surface. Thus the cooling plate has to be longer or wider than the photovoltaic cell plate, which costs much more material and prevents the dissipated heat from being additionally utilized. Moreover, in the heat sink the heat tube is located in the water tank heat exchanger, which affects the life of the heat tube unfavourably and causes a sealing leakage problem between the plate heat tube and the heat exchanger. At the same time, as the overheating phenomenon at individual spots occurs usually in the application of the photovoltaic cell plate and the cooling plate is usually assembled by a plurality of blocks, unsuitable assembly will render a problem that the heat generated by the spots cannot be radiated in time. In this case, local overheating is caused, and thus power generation efficiency and life of the photovoltaic cell will be adversely affected.

### SUMMARY

The invention aims to solve the problems in the prior art, that is, low efficiency and short life of photovoltaic cells due to overheating at the whole cells or some spots thereof that may be caused by insufficient dissipation of photovoltaic cells, and provides an efficient heat sink for solar photovoltaic cells, which can dissipate heat from solar photovoltaic cells quickly and effectively when employed to engage with the building surface and when employed as a building component. Therefore, heat dissipation of the cell plates is balanced and overheating at individual spots is avoided. In this way, solar utilization efficiency is improved, life of solar cells is prolonged, and the cost of the solar photovoltaic industry is decreased. The invention also relates to an efficient solar photovoltaic cell which employs the device, a combined heat and power generation system and the components special for the device.

An efficient heat sink for solar photovoltaic cells, used for dissipating heat therefrom, is characterized in that, it comprises one or more flat plate heat pipes, wherein a front plate surface of the front and back plate surfaces of which directly engages or indirectly engages with the backplate of the cell plate, and covers the whole backplate of the cell plate; and further comprises a heat exchanger of plate pipe type that engages with the cooling portion of backplate surface of the flat plate heat pipe; the flat plate heat pipe includes therein one or more heat pipes arranged side by side; the heat exchanger is a through-pipe with an engaging surface on one side thereof; the engaging surface extends along the longitudinal direction of the through-pipe; the through-pipe strides across the heat pipes of the flat plate heat pipe; and the through-pipe has a connecting head and/or connecting port to be connected with other pipelines.

The length of the flat plate heat pipe is close to, but not larger than, that of the cell plate, and there are two or more heat pipes within the flat plate heat pipe, and the phrase directly engaging, or its variation, means that two or more flat plate heat pipes are arranged closely side by side, with the distance therebetween less than 5mm, and the front plate surfaces thereof are tightly engaged directly with the backplate of the cell plate; the phrase, indirectly engaging, and its variation, means that a metal plate with good conductivity for the whole plate or a plurality of metal plates engaged with each other closely with good conductivity in a whole, are arranged between the backplate of the cell plate and the front plate surface of the one or more flat plate heat pipes.

The width of the engaging surface is between 20 mm and 300 mm, and the inner diameter of through-pipe is between 5 mm and 60 mm.

The phrase, engaging, or its variation, refers to engagement of dry type, without welding, or engagement by means of adhesive.

The heat exchanger of plate pipe type is a unilateral heat exchanger designed with an engaging surface only on one side of the through-pipe, and the wall thickness of the through-pipe on the side opposite to the engaging surface is between 10 mm and 6 mm; alternatively, the heat exchanger is a bilateral heat exchanger designed with an engaging surfaces separately on both sides relative to the through-pipe.

The flat plate heat pipe is a micro heat pipe array of flat plate type formed by extruding or stamping for metal or alloy, and the backplate surface of the flat plate heat pipes and the surface of the heat exchanger except the engaging portion are coated with coating of high radiation rate; the engaging surface of the heat exchanger strides across each micro heat pipe.

An efficient solar photovoltaic cell plate employing the heat sink, comprising a cell plate, is characterized in that, it further comprises one or more flat plate heat pipes matching with the cell plate in size; wherein a front plate surface of the front and back plate surfaces of which directly engages or indirectly engages with the backplate of the cell plate, and covers the whole backplate of the cell plate; and further comprises a heat exchanger of plate pipe type that engages with the cooling portion of backplate surface of the flat plate heat pipe; the flat plate heat pipe includes therein one or more heat pipes arranged side by side; the heat exchanger is a through-pipe with an engaging surface on one side thereof; the engaging surface extends along the longitudinal direction of the through-pipe; the through-pipe strides across the heat pipes of the flat plate heat pipe; and the through-pipe has a connecting head and/or a connecting port to be connected with other pipelines.

The length of the flat plate heat pipe is close to, but not larger than, that of the cell plate, and there are two or more heat pipes within the flat plate heat pipe, and the phrase directly engaging, or its variation, means that two or more flat plate heat pipes are arranged closely side by side, with the distance therebetween less than 5 mm, and the front plate surfaces thereof are tightly engaged directly with the backplate of the cell plate; the phrase, indirectly engaging, and its variation, means that a metal plate with good conductivity for the whole plate or a plurality of metal plates engaged with each other closely with good conductivity in a whole, are arranged between the backplate of the cell plate and the front plate surface of the one or more flat plate heat pipes.

The width of the engaging surface is between 20 mm and 300 mm, and the inner diameter of through-pipe is between 5 mm and 60 mm.

The phrase, engaging, or its variation, refers to engagement of dry type, without welding, or engagement by means of adhesive.

The heat exchanger of plate pipe type is a unilateral heat exchanger designed with an engaging surface only on one side of the through-pipe, and the wall thickness of the through-pipe on the side opposite to the engaging surface is between 10 mm and 6 mm; alternatively, the heat exchanger is a bilateral heat exchanger designed with an engaging surfaces separately on both sides relative to the through-pipe.

The flat plate heat pipe is a micro heat pipe array of flat plate type formed by extruding or stamping for metal or alloy, and the engaging surface of the heat exchanger strides across each micro heat pipe.

The cell plate and the flat plate heat pipes which are matching with each other in size are assembled as a whole through a frame, and ratio of the width of the engaging surface of the heat exchanger in the frame to the length of the flat plate heat pipe is from 1/20 to ⅕, preferably from 1/10 to ⅕.

The efficiency solar photovoltaic cells plates are arranged closely side by side.

A combined heat and power generation system employing the efficient solar photovoltaic cell plate, comprising a cell, is characterized in that, it further comprises one or more flat plate heat pipes matching with the cell plate in size, wherein a front plate surface of the front and back plate surfaces of which directly engages or indirectly engages with the backplate of the cell plate, and covers the whole backplate of the cell plate; and further comprises a heat exchanger of plate pipe type that engages with the cooling portion of backplate surface of the flat plate heat pipe; the flat plate heat pipe includes therein one or more heat pipes arranged side by side; the heat exchanger is a through-pipe with an engaging surface on one side thereof; the engaging surface extends along the longitudinal direction of the through-pipe; the through-pipe strides across the heat pipes of the flat plate heat pipe; and the through-pipe is connected to a pump, an air cooling heat exchanger for overheating protection, and a water tank through a pipeline to form a circular loop.

The length of the flat plate heat pipe is close to, but not larger than, that of the cell plate, and there are two or more heat pipes within the flat plate heat pipe, and the phrase directly engaging, or its variation, means that two or more flat plate heat pipes are arranged closely side by side, with the distance therebetween less than 5 mm, and the front plate surfaces thereof are tightly engaged directly with the backplate of the cell plate; the phrase, indirectly engaging, and its variation, means that a metal plate with good conductivity for the whole plate or a plurality of metal plates engaged with each other closely with good conductivity in a whole, are arranged between the backplate of the cell plate and the front plate surface of the one or more flat plate heat pipes.

The width of the engaging surface is between 20 mm and 300 mm, and the inner diameter of through-pipe is between 5 mm and 60 mm, and the wall thickness of the through-pipe on the side opposite to the engaging surface is between 1.0 mm and 6 mm

The phrase, engaging, or its variation, refers to engagement of dry type, without welding, or engagement by means of adhesive; the heat exchanger of plate pipe type is a unilateral heat exchanger designed with an engaging surface only on one side of the through-pipe, and the wall thickness of the through-pipe on the side opposite to the engaging surface is between 10 mm and 6 mm; alternatively, the heat exchanger is a bilateral heat exchanger designed with an engaging surfaces separately on both sides relative to the through-pipe,

The flat plate heat pipe is a micro heat pipe array of flat plate type formed by extruding or stamping for metal or alloy, and the engaging surface of the heat exchanger strides across each micro heat pipe.

The cell plate and the flat plate heat pipes which are matching with each other in size are assembled as a whole through a frame, and ratio of the width of the engaging surface of the heat exchanger in the frame to the length of the flat plate heat pipe is from 1/20 to ⅕, preferably from 1/10 to ⅕.

The close connection between the efficiency solar photovoltaic cells plates is realized through a bilateral plate pipe.

The combined heat and power generation system maintains the temperature of the silicon photovoltaic cell within 50° C. and generates hot water within 45° C.; alternatively the temperature of the amorphous photovoltaic cell is maintained within 90° C. and hot water within 80° C. is generated.

The heat exchanger of plate pipe type is a through-pipe with an engaging surface on one side thereof; the engaging surface extends along the longitudinal direction of the through-pipe; and the through-pipe has a connecting head and/or connecting port to be connected with other pipelines.

The through-pipe is designed with an engaging surface on only one side thereof, alternatively the through-pipe is designed with an engaging surface and a connecting surface on opposite sides.

The engaging surface and/or the connecting surface, together with the through-pipe, are a holistic structure; alternatively, they are a separate structure that can be assembled as a whole, that is, the engaging surface is a surface of a plate structure whose length is less than or equal to that of the through-pipe, and the surface of the plate structure that is opposite to the engaging surface is designed with an arc structure that matches with the through-pipe, and this separate structure also applies to the case in which the connecting surface and the through-pipe are separate.

The engaging surface and/or the connecting surface connects with the outer surface of the through-pipe through a concave surface.

Technical effects of the invention are as follows.

The invention provides an efficient heat sink for solar photovoltaic cells, an efficient solar photovoltaic cell plate employing the heat sink and a combined heat and power generation system employing the efficient solar photovoltaic cell plate. Since the front plate surface of the plate heat tube directly or indirectly engages with the backplate of the cell plate, and the heat exchanger of plate pipe type with a special structure engages with the cooling portion of backplate surface of the flat plate heat pipe, heat absorbed quickly by the heat absorption surface of the flat plate heat pipe (the front plate surface) from the cell plate can be dissipated quickly by the heat exchanger of plate pipe type from through-pipe through cooling media, such as water or antifreeze, without affecting combination of the cell plate with a building surface or application of the cell plate as a building component. Therefore, the temperature of the cell plate is prevented from rising, and the dissipated heat may be utilized effectively to generate hot water, solar utilization efficiency is improved, and the cost of the solar photovoltaic industry is reduced. Besides, since the need is dispensed with that a building envelope has to be provided for cooling in the case of integral design for the solar photovoltaic cell and the building, the contradiction between cooling of the cell backplate and heat insulation of the building envelope is resolved.

### BRIEF DESCRIPTION OF THE DRAWINGS

FIG. 1 is the schematic exploded structure view of the efficient heat sink for solar photovoltaic cells according to the invention.

FIG. 2 is the schematic structure view showing the cross section of the unilateral heat exchanger of plate pipe type according to the invention.

FIG. 3 is the schematic structure view showing the cross section of the bilateral heat exchanger of plate pipe type according to the invention.

FIG. 4 is the schematic structure view of the natural convection heating of three efficiency solar photovoltaic cells plates according to the invention, which are not arranged closely.

FIG. 5 is the schematic structure view of the forced convection heating of three efficiency solar photovoltaic cells plates according to the invention, which are not arranged closely.

FIGS. 6a and 6b are the schematic structure back view and side view of the efficient solar photovoltaic cell plate designed with a peripheral frame, respectively, and FIG. 6c is the cross section of the unilateral heat exchanger of plate pipe type thereof

FIGS. 7a and 7b are the schematic structure back view and side view of the high efficient solar photovoltaic cell plate designed with a peripheral frame, respectively, and FIG. 7c is the cross section of the bilateral plate pipe heat exchanger of plate pipe type thereof.

FIG. 8 depicts the coarse assembly of a plurality of efficient solar photovoltaic cells plates according to the invention.

FIG. 9 depicts the compact assembly of a plurality of efficient solar photovoltaic cells plates according to the invention.

FIG. 10 is the schematic structure view showing the application of the combined heat and power generation system according to the invention as a heat recovery type solar photovoltaic power station system.

FIG. 11 is the schematic structure view showing the application of the combined heat and power generation system according to the invention as a heat rejection type solar photovoltaic power station system.

### DETAILED DESCRIPTION OF THE PREFERRED EMBODIMENTS

Hereinafter the invention will be further explained with reference to the accompanying figures.

FIG. 1 is the schematic exploded structure view of the high efficient heat sink for solar photovoltaic cells according to the invention. The efficient heat sink for solar photovoltaic cells shown in FIG. 1, which can be utilized to cool solar photovoltaic cell plate 1, comprises of one or more flat plate heat pipes 2. Preferably, the length of flat plate heat pipes 2 is similar to, but not larger than that of the cell plate, thus materials can be saved and the cell plates can be assembled conveniently. FIG. 1 shows a plurality of flat plate heat pipes 2 in a side by side arrangement, in which the front plate surface of the front and back plate surfaces of the flat plate heat pipes 2 directly engages or indirectly engages with the backplate of the cell plate 1. In this embodiment, the plurality of flat plate heat pipes 2 arranged side by side match the cell plate 1 in size, and the front plate surfaces thereof cover the whole backplate of the cell plate 1. Each flat plate heat pipe 2 has therein one or more heat pipes that are arranged side by side. Preferably, the flat plate heat pipe 2 has therein two or more heat pipes. More preferably, the flat plate heat pipe 2 is a micro heat pipe array of flat plate type formed by extruding or stamping for metal or alloy, in this way the flat plate heat pipe 2 has high heat-exchange efficiency and sufficient resistance against compression.

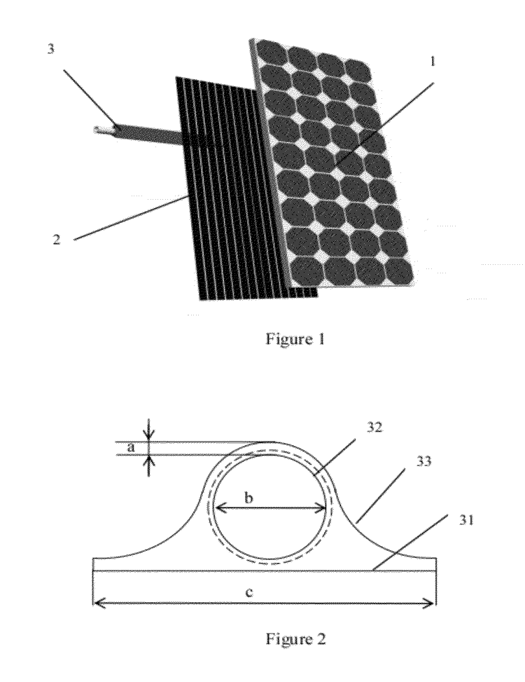

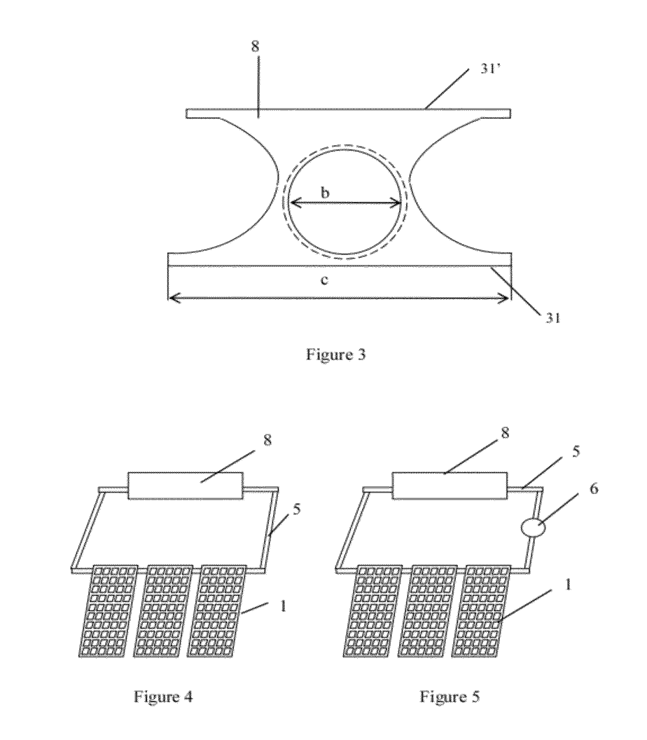

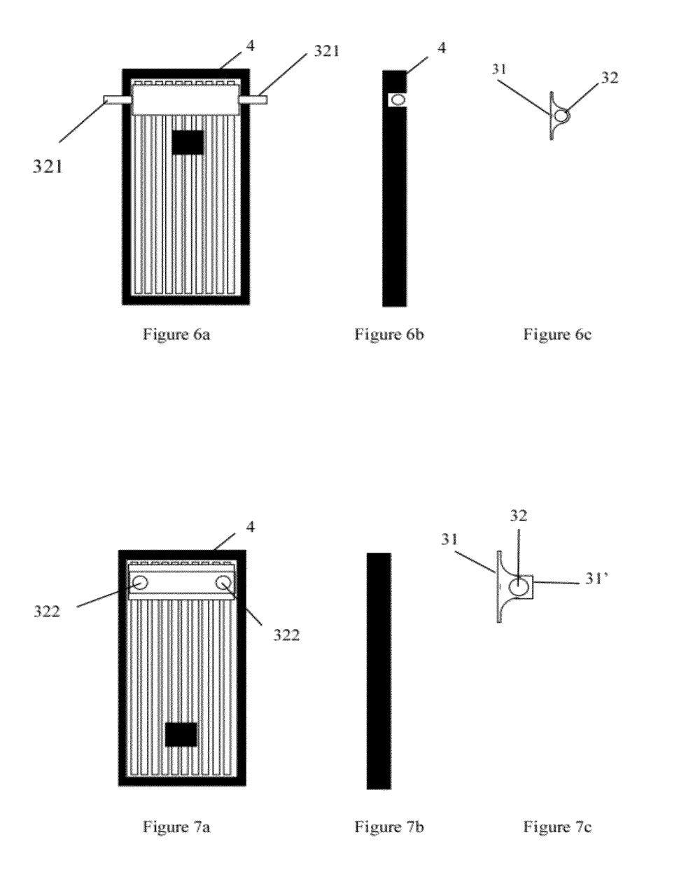

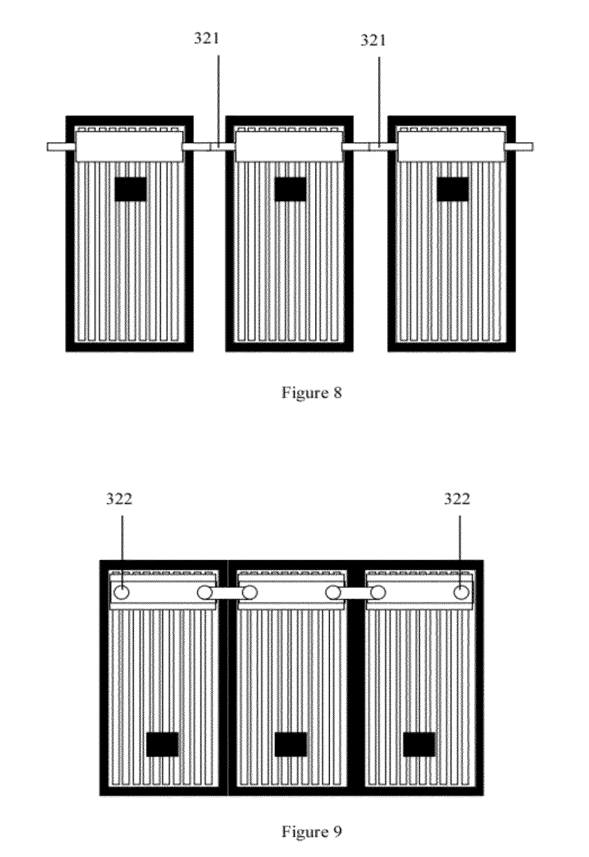

The efficient heat sink for solar photovoltaic cells also comprises a heat exchanger 3 of plate pipe type that engages with the cooling portion of backplate surface of the flat plate heat pipe 2. The structure of the heat exchanger 3 of plate pipe type is shown in FIGS. 2 and 3. As shown, the heat exchanger 3 is a through-pipe 32 with an engaging surface 31 for engaging on one side thereof, which extends along the longitudinal direction of the through-pipe 32. The through-pipe 32 strides across the flat plate heat pipe 2 and micro heat pipes therein in such a way that each heat pipe may exchange heat with the heat exchanger 3. Preferably the longitudinal direction of the through-pipe 32 is perpendicular or substantially perpendicular to the longitudinal direction of the heat pipes within the flat plate heat pipe 2, thus the engaging surface 31 of the heat exchanger 3 strides across micro heat pipes. The through-pipe 32 has a connecting head 321 and / or connecting port 322 (shown in FIGS. 6a and 7a) to be connected with other pipelines.

The phrase directly engaging, or its variation, means that two or more flat plate heat pipes 2 are arranged closely side by side, with the distance therebetween less than 5 mm, and the front plate surfaces thereof are tightly engaged directly with the backplate of the cell plate 1. The phrase, indirectly engaging, and its variation, means that a metal plate with good conductivity for the whole plate, such as an aluminum plate is arranged between the backplate of the cell plate 1 and the front plate surface of the flat plate heat pipe 2. The metal plate may be an integral plate, or may be formed by two or more metal plates that are arranged closely. In the case that a metal plate of good conductivity and high uniformity is sandwiched between the backplate of cell plate 1 and the flat plate heat pipe 2, the flat plate heat pipe 2 that are arranged side by side may not be close. There may be a clearance therebetween, or, the distance between the flat plate heat pipes 2 arranged side by side may be greater than 5 mm. Thus, it is ensured that heat can be uniformly dissipated quickly even in the case that intensive heat is generated at individual spots through a close side-by-side arrangement of the flat plate heat pipes 2 or a sandwiching arrangement of a metal plate of good and uniform conductivity between the backplate of the cell plate 1 and the flat plate heat pipes 2, in this way, the problems of low efficiency of the cell and decreased endurance that would otherwise result from the increased temperature due to these spots are avoid.

The width c of the engaging surface 31 is between 20 mm and 300 mm, and the inner diameter b of through-pipe 32 is between 5 mm and 60 mm.

The phrase, engaging, or its variation, refers to engagement of dry type, without welding, or engagement by means of adhesive. The adhesive may be silica or other heat conductive glue. Preferably the adhesive has good heat conductivity and a lifespan up to 20-30 years.

According to another embodiment, the heat exchanger 3 may be a unilateral heat exchanger designed with an engaging surface 31 only on one side of through-pipe 32, as shown in FIG. 2. In this case, the wall thickness of the through-pipe 32 on the side opposite to the engaging surface 31 is between 1.0mm and 6mm Alternatively, the heat exchanger 3 is a bilateral heat exchanger designed with an engaging surface 31 and a connecting surface 31′ on both sides relative to the through-pipe 32, as shown in FIG. 3. The engaging surface 31 and/or the connecting surface 31′, together with the through-pipe 32, may be of, but not necessarily, a holistic structure, such as shown in FIGS. 2 and 3. They may be of a separate structure. The engaging surface 31 and/or the connecting surface 31′ is a surface of a plate structure whose length is less than or equal to that of the through-pipe 32. The surface of the plate structure that is opposite to the engaging surface 31 is designed with an arc structure that matches with the through-pipe 32. This separate structure also applies to the case in which the connecting surface 31′ and the through-pipe 32 are separate. The engaging surface 31 and the connecting surface 31′ may be symmetrical or asymmetrical. Preferably they are symmetrical, and the area of connecting surface 31′ is preferably less than that of the engaging surface 31.

The engaging surface 31 and/or the connecting surface 31′ connects with the surface of the through-pipe 32 through a concave surface 33, thus material is saved and heat conduction is ensured.

Furthermore, it is preferable that the backplate surface of the flat plate heat pipes 2 arranged side by side and the surface of the heat exchanger 3 except the engaging portion are coated with coating of high radiation rate, such as ceramic coating. When the temperature of cell plate 1 is increased (to above 50° C., hypothetically), the front plate surface of the flat plate heat pipe 2 absorbs heat of the cell plate 1 as a heat absorption surface, and most of the heat of the cell plate 1 is quickly transported by the heat exchanger 3 of plate pipe type contacted on the backplate surface of the flat plate heat pipe 2. At the same time, another part of the heat of the flat plate heat pipe 2 can be dissipated by the coating of high radiation rate. Thus the heat conduction efficiency of the flat plate heat pipe 2 can be improved by the coat of high radiation rate. Further, even in the case in which the flat plate heat pipe 2 is damaged and thus cannot generate heat tube effect, the heat of the cell plate 1 can be dissipated through the coating of high heat radiation rate coated on the flat plate heat pipe 2. In this sense, the coating of high radiation rate provides double protections.

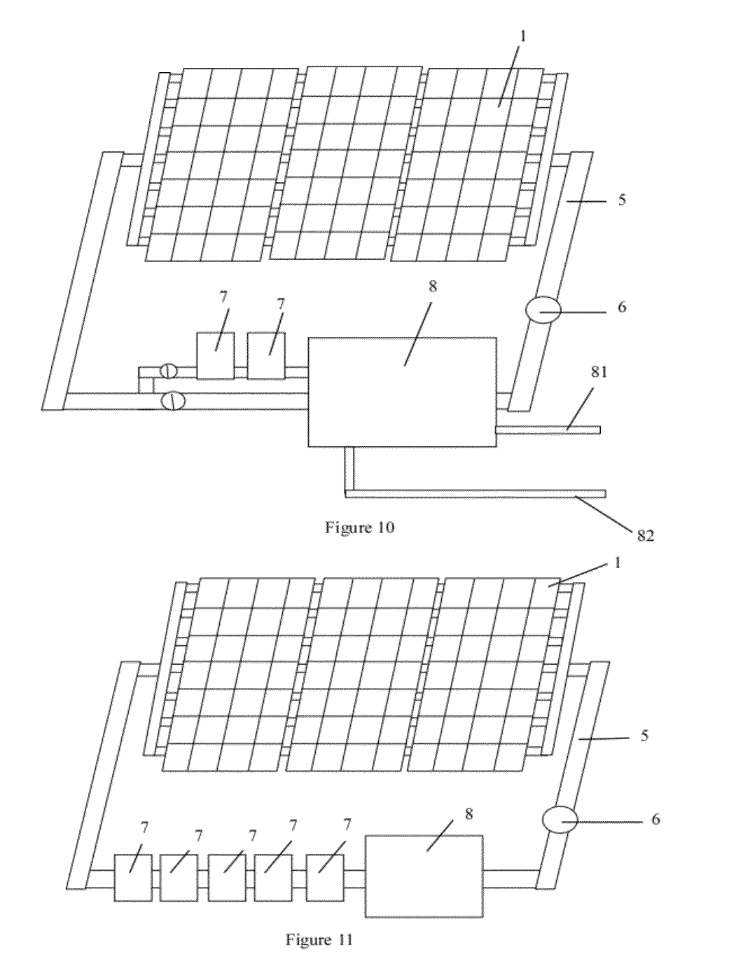

An efficient solar photovoltaic cell plate employing the heat sink shown in FIG. 1 and its applications are shown in FIGS. 4-11. The cell plate comprises a cell plate 1 and an efficient heat sink for solar photovoltaic cells engaged closely with the backplate of the cell plate. The flat plate heat pipes 2 arranged side by side should match with the backplate of the cell plate 1 in size. Preferably, they are fixed in a rectangle frame (such the frame 4 as shown in FIGS. 6a and 7a) after being closely engaged with each other (this also applies to the situation in which a uniform aluminum plate is sandwiched therebetween). The connecting head 321 connecting the through-pipe 32 and other pipelines can go through two sides of the frame 4, as shown in FIGS. 6a and 6b. Thus by means of the connecting head, it is not necessary for the efficient solar photovoltaic cells to be arranged closely, as shown in FIG. 8. This kind of the heat exchanger 3 of plate pipe type can be embodied as the unilateral heat exchanger as shown in FIG. 2, with the connection state shown in FIG. 6c. The through-pipe 32 is connected to other pipelines through the connecting head or the connecting port 322, which, different from the connecting head 321, projects from the portion of the heat exchanger 3 of plate pipe type that is located within the frame 4, as shown in FIGS. 7a and 7b. This kind of the heat exchanger 3 of plate pipe type is preferably embodied as the bilateral heat exchanger shown in FIG. 3 so as to arrange connecting pipelines on the connecting surface 31′ corresponding to the engaging surface 31. In this case, the connecting head or the connecting port 322 does not pass through two sides of the frame 4, but still can connect a plurality of efficient solar photovoltaic cells plates. The efficiency solar photovoltaic cells may be arranged closely, or be design with waterproof connection, as shown in FIG. 9. The setting mode of the bilateral heat exchanger 3 is shown in FIG. 7c, wherein the width of the connecting surface 31′ used for the connection is preferably less than that of the engaging surface 31 so as to save material.

The cell plate 1 and the flat plate heat pipe 2 can be assembled as a whole through the frame 4, and ratio of the width of the engaging surface 31 of the heat exchanger 3 of plate pipe type in the frame 4 to the length of the flat plate heat pipe is from 1/20 to ⅕, preferably from 1/10 to ⅕. Through employing the width within this range, a high efficient heat exchanging can be assured, and material is saved, thus the weight of the heat exchanger of plate pipe type is decreased. It is obvious that a plurality of heat exchangers 3 of plate pipe type may be arranged transversely on the backplate surface of the flat plate heat pipe 2. In this case, the connecting heads or the connecting ports thereof can be connected to external pipelines after being connected in parallel. In this case, the sum of the widths of the engaging surfaces 31 of the heat exchangers 3 of plate pipe type preferably ranges from 1/20 to ⅕ of the length of the flat plate heat pipe, preferably from 1/10 to ⅕. The sum of the width c of the engaging surfaces 31 ranges from 20 mm to 300 mm, and the sum of the inner diameter b of through-pipes ranges from 5 mm to 60 mm.

A combined heat and power generation system employing the efficient solar photovoltaic cell plate comprises an efficient solar photovoltaic cell plate 1, wherein the through-pipe 32 is connected to a pump 6 and a water tank 8 through a pipeline 5 to form a circular loop, so as to provide heat, as shown in FIG. 5 which is the schematic structure view of the forced convection heating of three efficiency solar photovoltaic cells plates according to the invention that are not arranged closely. A natural convection heating would be formed when the pump 6 is dispensed with, as shown in FIG. 4 which is the schematic structure view of the natural convection heating of three efficiency solar photovoltaic cells plates according to the invention that are not arranged closely. FIG. 10 depicts a combined heat and power generation system of heat recovery type, wherein the water tank 8 has a large volume, the pipeline 5 may be provided with a plurality of, or a few of air cooling heat exchangers 7 for overheating protection, or not provided at all. The water tank 8 is provided with an inlet pipe 81 and an outlet pipe 82. The cool water is input from the inlet pipe. The cool water is heated by the heat conducted from the working medium in the pipeline 5. The heated water is output from the outlet pipe 82 so to as to provide heat. FIG. 11 depicts a solar photovoltaic cell plate of heat rejection type which is used only for power generation. In this case, the water tank 8 has a small volume, the pipeline 5 should be designed with a few of, or a plurality of air cooling heat exchanger 7 for overheating protection to dissipate heat. The temperature of the efficient solar photovoltaic cell can be monitored. One or more air cooling heat exchangers 7 can be turned on once the temperature exceeds the set value and hence the water tank 8 dose not dissipate well. Thus, the power generation efficiency of the efficiency solar photovoltaic cells plates according to the invention is improved considerably, and the life thereof is increased greatly. The combined heat and power generation system shown in FIG. 10 maintains the temperature of the silicon photovoltaic cell within 50° C. and generates hot water within 45° C. Alternatively the temperature of the amorphous photovoltaic cell is maintained within 90° C. and hot water within 80° C. is generated.

Therefore, the solar photovoltaic combined heat and power generation system according to the invention can be designed effectively for building. For building attached photovoltaic (BAPV), the efficient solar photovoltaic cell plate can be attached on the building roof or on the wall surface, and the relative power generation efficiency can be increased by 15% to 30%. Hot water at about 40° C. to 45° C. can be provided for building heating or human using, and so on. The solar utilization efficiency of the system amounts to 50-60%.

For building integrated photovoltaic (BIPV), the solar photovoltaic cell plate according to the invention can be used as a building component; the relative power generation efficiency can be increased by 15% to 30%; Hot water at about 40° C. to 45° C. can be provided for building heating or human using, and so on. The solar utilization efficiency of the system amounts to 50-60%.

For the solar photovoltaic combined heat and power generation system of heat recovery type, centralized heating can be fulfilled through utilizing waste heat while cooling the cell plate, and the relative power generation efficiency can be increased by 15% to 30%. Hot water at about 40° C. to 45° C. can be provided for centralized heating or other applications.

The efficient solar photovoltaic cell plate can be applied to the solar photovoltaic power station of heat rejection type. The solar photovoltaic power station can be built in desert or non-residential areas, wherein waste heat cannot be utilized and cooling the cell plate is the only purpose of heat dissipation. The air cooling heat exchanger 7 must be provided. The relative power generation efficiency can be increased by 15% to 30% due to employing the efficient solar photovoltaic cell plate. When the water temperature is higher than the outside temperature, the waste heat is discharged by the cooling circulation system through efficient natural air cooling heat exchanger.

1. An efficient heat sink for solar photovoltaic cells, used for dissipating heat therefrom, comprising:
one or more flat plate heat pipes, wherein a front plate surface of the front and back plate surfaces directly engages or indirectly engages with the backplate of the cell plate, and covers the whole backplate of the cell plate; and
a heat exchanger of plate pipe type that engages with the cooling portion of backplate surface of the flat plate heat pipe wherein:
the flat plate heat pipe includes therein one or more heat pipes arranged side by side;
the heat exchanger is a through-pipe with an engaging surface on one side thereof;
the engaging surface extends along the longitudinal direction of the through-pipe;
the through-pipe strides across the heat pipes of the flat plate heat pipe; and the through-pipe has a connecting head and/or connecting port to be connected with other pipelines.

2. The efficient heat sink for solar photovoltaic cells according to claim 1, wherein:
the length of the flat plate heat pipe is close to, but not larger than, that of the cell plate,
there are two or more heat pipes within the flat plate heat pipe,
if the front plate surface directly engages with the backplate, two or more flat plate heat pipes are arranged closely side by side, with the distance therebetween less than 5 mm, and the front plate surfaces thereof are tightly engaged directly with the backplate of the cell plate; and
if the front plate surface indirectly engages with the backplate, a metal plate with good conductivity for the whole plate or a plurality of metal plates engaged with each other closely with good conductivity in a whole, are arranged between the backplate of the cell plate and the front plate surface of the one or more flat plate heat pipes.

3. The efficient heat sink for solar photovoltaic cells according to claim 1, wherein:
the front plate surface engages with the backplate with engagement of dry type, without welding, or engagement by means of adhesive; and
the width of the engaging surface is between 20 mm and 300 mm, and the inner diameter of through-pipe is between 5 mm and 60 mm.

4. The efficient heat sink for solar photovoltaic cells according to claim 1, wherein:
the heat exchanger of plate pipe type is a unilateral heat exchanger designed with an engaging surface only on one side of the through-pipe, and
the wall thickness of the through-pipe on the side opposite to the engaging surface is between 1.0 mm and 6 mm.

5. The efficient heat sink for solar photovoltaic cells according to claim 1, wherein:
the flat plate heat pipe is a micro heat pipe array of flat plate type formed by extruding or stamping for metal or alloy,
the backplate surface of the flat plate heat pipes and the surface of the heat exchanger except the engaging portion are coated with coating of high radiation rate; and
the engaging surface of the heat exchanger strides across each micro heat pipe.

6. An efficient solar photovoltaic cell plate, comprising:
a cell plate that engages with the flat plate heat pipe of the efficient heat sink for solar photovoltaic cells according to claim 1.

7. The efficient solar photovoltaic cell plate according to claim 6, wherein the cell plate and the flat plate heat pipes which are matching with each other in size are assembled as a whole through a frame, and ratio of the width of the engaging surface of the heat exchanger in the frame to the length of the flat plate heat pipes is from 1/20 to ⅕.

8. The efficient solar photovoltaic cell plate according to claim 7, wherein ratio of the width of the engaging surface of the heat exchanger in the frame to the length of the flat plate heat pipes is from 1/10 to ⅕.

9. The efficient solar photovoltaic cell plate according to claim 6, wherein the efficiency solar photovoltaic cells plates are arranged closely side by side.

10. A combined heat and power generation system, comprising:
the efficient solar photovoltaic cell plate according to claims 6, wherein the through-pipe is connected to a pump and a water tank through a pipeline to form a circular loop.

11. The combined heat and power generation system according to claim 10, wherein the pipeline is designed with an air cooling heat exchanger for overheating protection.

12. The combined heat and power generation system according to claim 10, wherein the combined heat and power generation system maintains the temperature of the silicon photovoltaic cell within 50° C. and generates hot water within 45° C.; alternatively the temperature of the amorphous photovoltaic cell is maintained within 90° C. and hot water within 80° C. is generated.

13. A heat exchanger of plate pipe type, wherein:
the heat exchanger of plate pipe type is a through-pipe with an engaging surface on one side thereof;
the engaging surface extends along the longitudinal direction of the through-pipe; and
the through-pipe has a connecting head and/or connecting port to be connected with other pipelines.

14. The heat exchanger of plate pipe type according to claim 13, wherein the through-pipe is designed with an engaging surface on only one side thereof.

15. The heat exchanger of plate pipe type according to claim 13, wherein:
the engaging surface and/or the connecting surface and the through-pipe, are a holistic structure or the engaging surface and/or the connecting surface and the through-pipe are separate structures that can be assembled as a whole, such that the engaging surface is a surface of a plate structure whose length is less than or equal to that of the through-pipe, and the surface of the plate structure that is opposite to the engaging surface is designed with an arc structure that matches with the through-pipe; and
the engaging surface and/or the connecting surface connects with the outer surface of the through-pipe through a concave surface.

16. The efficient heat sink for solar photovoltaic cells according to claim 1, wherein the heat exchanger is a bilateral heat exchanger designed with engaging surfaces separately on both sides relative to the through-pipe.

17. The heat exchanger of plate pipe type according to claim 15, wherein each of the engaging surface, the connecting surface and the through-pipe are separate structures.
